(19) United States
(12) Patent Application Publication
(10) Pub. No.: US 2024/0429124 A1
(43) Pub. Date: Dec. 26, 2024

(54) ELECTRONIC MODULE COMPRISING AT LEAST ONE POWER SEMICONDUCTOR, AND METHOD FOR PRODUCING SAME

(71) Applicant: Robert Bosch GmbH, Stuttgart (DE)

(72) Inventors: Arne Stephen Fischer, Leinfelden-Echterdingen (DE); Hartmut Wayand, Pfullingen (DE); Johannes Meckbach, Tuebingen (DE); Lukas Loeber, Ludwigsburg (DE); Thomas Kiedrowski, Sersheim (DE)

(21) Appl. No.: 18/684,079

(22) PCT Filed: Jul. 29, 2022
(86) PCT No.: PCT/EP2022/071347

§ 371 Date: Feb. 15, 2024

(30) Foreign Application Priority Data
Aug. 30, 2021 (DE) 10 2021 209 482.1

(51) Int. Cl. H01L 23/46; H01L 21/48; H01L 23/00; H01L 23/367; H01L 23/495

(52) U.S. Cl. CPC H01L 23/46; H01L 21/4882; H01L 23/3675; H01L 23/49537; H01L 24/32; H01L 24/33; H01L 2224/32245; H01L 2224/33181

(57) ABSTRACT

An electronic module. The electronic module includes at least one power semiconductor electrically connected to a contacting arrangement, and at least one cooling element for at least indirectly cooling the at least one power semiconductor.

### FIELD

The present invention relates to an electronic module including at least one power semiconductor which can be simultaneously cooled and electrically contacted by means of a cooling element. The present invention also relates to a method for producing an electronic module.

### BACKGROUND INFORMATION

German Patent Application No. DE 10 2014 221 147 A1 describes an electronic module comprising at least one power semiconductor. On opposite sides, the conventional electronic module has heat sinks arranged in operative connection with the power semiconductor via a multi-layer structure, which heat sinks cause heat to dissipate from the power semiconductor. The cooling elements designed as prefabricated components and used exclusively for cooling the power semiconductor are thermally coupled to the power semiconductor via connection layers.

### SUMMARY

An electronic module according to an example embodiment of the present invention includes at least one power semiconductor may have an advantage that it enables the integration of a cooling element in a multi-layer structure of the module in a particularly advantageous manner, wherein the cooling element is simultaneously used for the electrical contacting of the power semiconductor with a contacting arrangement. Control or coupling of the power semiconductor to a circuit takes place via the contacting arrangement. In addition, the electronic module makes it possible in a particularly simple manner to provide cooling elements that are optimized for the particular application.

The present invention includes forming the cooling element by means of a generative or additive production method, namely, in such a way that this intermediate element used as the electrical contacting is arranged between the power semiconductor and the contacting arrangement.

Against the background of the above explanations, it is therefore provided to provide an electronic module according to an example embodiment of the present invention including at least one power semiconductor according to the present invention in such a way that the at least one cooling element is designed as a cooling element produced in an additive manufacturing method, and that the at least one cooling element is arranged between the at least one power semiconductor and the contacting arrangement and electrically connects the at least one power semiconductor to the contacting arrangement.

Advantageous developments of the electronic module according to the present invention comprising at least one power semiconductor are disclosed herein.

A very particularly preferred development of a module according to the present invention provides that the at least one cooling element is built up from a plurality of layers, and that the layers form a channel for guiding a cooling medium. Such a design thus, in particular, makes it possible to provide a closed cross section for guiding the cooling medium or to form corresponding channels. In particular, a gas, but alternatively also a cooling liquid, is in this case possible as a cooling medium.

A further, particularly preferred structural design according to the present invention for reducing thermomechanical stresses or loads of the module in the region of the power semiconductor provides that the at least one cooling element has a lower rigidity in a direction perpendicular to the surface of the power semiconductor than in a direction parallel to the surface of the power semiconductor. In other words, this means that the cooling element has a certain flexibility in a direction perpendicular to the surface of the power semiconductor in order to compensate for the mentioned stresses perpendicularly to the surface of the power semiconductor. Ideally, the cooling element thus forms a type of spring element. However, the cooling element also has a certain elasticity or spring effect in the other direction parallel to the plane of the power semiconductor in order to compensate for mechanical stresses in this direction. Ultimately, the design of the geometry of the cooling element or the stiffness thereof takes place according to the particular application or the stiffness can be optimized in a direction-dependent manner.

A structurally particularly preferred design of the cooling element provides that, on opposite sides, the at least one cooling element respectively has full-area first and third layers which are electrically connected to the power semiconductor or the contacting arrangement, and that second layers directly adjoin the full-area first and third layers and form the at least one channel for guiding the cooling medium.

In order to optimize the cooling or in order to be able to electrically contact the power semiconductor from different sides, it is moreover particularly advantageous if at least one cooling element is arranged on each of the two opposite sides of the at least one power semiconductor.

In order to improve the connection or secure the connection between the cooling element and the power semiconductor, according to an example embodiment of the present invention, it is provided that the at least one power semiconductor is connected to the at least one cooling element by means of a contacting layer, and that the material of the contacting layer is of the same type as the material of the heat sink. The fact that the materials of the heat sink and of the contacting layer, which can both, for example, consist of or comprise aluminum or copper, are of the same type enables an integral bond between the contacting layer and the material of the heat sink, in particular during the additive build-up or melting and subsequent solidification of the material of the heat sink (in the event that the additive build-up takes place via a plurality of layers consisting of metal powder and melted by means of a laser beam).

A further preferred design of the module for optimizing the cooling effect according to an example embodiment of the present invention provides that the at least one cooling element and the at least one power semiconductor are arranged within a housing receiving a cooling medium, and that the contacting arrangement is arranged outside the housing and, through preferably sealed openings formed in the housing, is connected via a connection element to the at least one cooling element.

In a preferred development of the present invention, it is provided that the connection element is designed as a monolithic part of the cooling element. The connection element, which is thus part of the cooling element or is produced together with the cooling element in the additive method, thus bridges the region between the cooling element, which is used for the actual cooling, and the contacting arrangement.

Furthermore, the present invention relates to a method for producing an electronic module which is preferably designed according to the above explanations, wherein the method according to the present invention comprises at least the following steps: First, a power semiconductor comprising at least one contacting layer is provided. Subsequently, at least one cooling element is formed in an additive manufacturing method on the surface of the at least one contacting layer. Finally, on the side facing away from the power semiconductor, the at least one cooling element is at least indirectly connected to a contacting arrangement.

In a preferred development of the method according to an example embodiment of the present invention, it is provided that, before the at least one cooling element is at least indirectly connected to the contacting arrangement, the at least one power semiconductor and the at least one cooling element are arranged within and the contacting arrangement is arranged outside a housing.

With regard to forming the cooling element, it is preferably provided that the additive formation of the at least one cooling element takes place by selectively melting and subsequently solidifying powder layers by means of a laser beam, and that the welding depth and/or the energy input of the laser beam is reduced when the lower or first layers of the cooling element that face the power semiconductor are formed. In particular, thermal overload of or damage to the power semiconductor is thereby avoided. The reduction of the welding depth is in this case possible to certain extents by adjusting the process parameters (e.g., laser power, laser travel speed, etc.). Alternatively or additionally, it is possible to use the melting of the material of the heat sink using a so-called ultra-short pulse laser. The pulsed laser radiation makes it possible, on the one hand, to enable high absorbed intensities (necessary for melting the starting material of the heat sink) with simultaneously comparatively low absorbed average power (necessary for the desired low thermal input into the power semiconductor). A very precise and above all very low welding depth can be achieved by a large number of very weak pulses (in the range between 1 MHz and 100 MHZ). An adjustment of the powder size distribution to smaller sizes (between 0.1 μm and 5μm) is also necessary in order to make this process possible. The layer thicknesses that can thereby be achieved thus also reach the same order of magnitude so that a relatively low build-up rate can be achieved. As soon as a certain build-up height (e.g., between 10 um and 100 um) of the heat sink is reached, the process can change to the traditional method.

A further possible adjustment of the production process would be the use of the so-called LTM method (LTM=Laser Transfer Metallization), which is a development of the LIFT method (LIFT=Laser Induced Forward Transfer). In the LTM method, a sacrificial film consisting of the material of the cooling element to be built up is melted above the substrate or power semiconductor. The melted material is deposited on the power semiconductor and forms a base layer of the structures of the cooling element that are to be built up, onto which base layer the cooling element can then be built up in the conventional powder bed method.

Alternatively, according to an example embodiment of the present invention, it can again be provided to reduce the thermal load on the power semiconductor during the additive build-up of the cooling element by the contacting layer on the power semiconductor on which the cooling element is built up having an increased thickness or height in comparison to the prior art. An increase by a few micrometers of the metallization in comparison to the prior art already results in a greatly enlarged process window for the additive process. This process window can possibly even be so great that the measures described above for reducing the energy input can be dispensed with. It is also possible to reduce the thermal load during the layer build-up of the cooling element by adjusting the material of the metallization. In principle, adjustments of the substrate or power semiconductor with regard to the entire layer system of the metallization are also possible.

The powder is preferably a metal powder. The metal powder consists of or contains copper and/or aluminum and/or a copper alloy and/or an aluminum alloy. Alternatively or additionally, the metal powder contains a composite comprising carbon. In a particularly advantageous manner, the additive build-up enables mixing of the materials mentioned to form a powder mixture in order thus to generate different alloys by the melting process.

Further advantages, features and details of the present invention result from the following description of preferred embodiments of the present invention and on the basis of the figure.

### BRIEF DESCRIPTION OF THE DRAWING

FIG. 1 shows a simplified longitudinal section of an electronic module including a power semiconductor using two cooling elements which are produced in the additive manufacturing method and are connected to a contacting arrangement.

### DETAILED DESCRIPTION OF EXAMPLE EMBODIMENTS

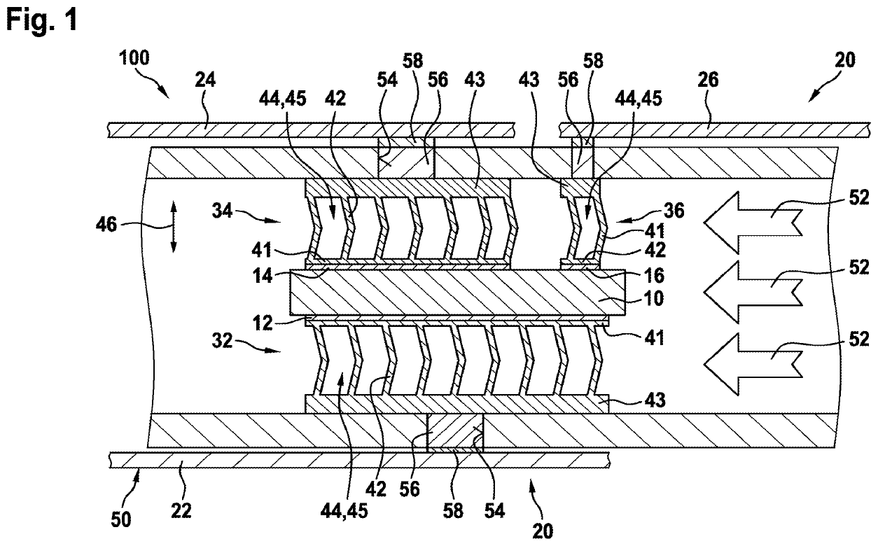

The electronic module 100 shown in FIG. 1 has a power semiconductor 10 which generates heat during operation and is formed in particular in the usual manner as a substrate. On the two opposite surfaces of the power semiconductor 10, contacting layers 12, 14, and 16 in the form of contact pads consisting of metal are provided, which are formed in the usual manner, for example by printing them from copper or aluminum. The contacting layers 12, 14, 16 are used to electrically contact the power semiconductor 10 with a contacting arrangement 20 having conductor tracks, lead frames or similar elements, wherein the contacting arrangement 20 has a respective connection element 22, 24, 26 for each of the contacting regions 12, 14, and 16.

The connection between the contacting regions 12, 14, 16 and the connection elements 22, 24, 26 of the contacting arrangement 20 takes place via, by way of example, three cooling elements 32, 34, 36 which are each produced in the additive manufacturing method.

By way of example, the cooling elements 32, 34, 36 each have at least one, typically a plurality of first layers 41, which are arranged in full-area overlap with the contacting layers 12, 14, 16 and are connected thereto. This is followed by a multitude of second layers 42, which shown according to FIG. 1, which, purely by way of example, form cavities 44 as part of channels 45 in the manner of a herringbone pattern. In this respect, it is moreover essential that the second layers 42 are arranged or formed in such a way that, by way of example, the cooling element 32, 34, 36 has a higher elasticity or a lower rigidity in a direction perpendicular to the plane of the surfaces of the power semiconductor 10, corresponding to the double arrow 46, than in a direction parallel to the surface of the power semiconductor 10. However, in a direction parallel to the plane of the surfaces of the power semiconductor 10, the cooling elements 32, 34, and 36 also have a rigidity that is lower than that of a cooling element 32, 34, 36 formed from solid material (i.e., without cavities 44). The second layers 42 thus have a dual function: On the one hand, they enable a direction-dependent adaptation of the rigidity or elasticity of the cooling element 32, 34, 36 to the particular application and, on the other hand, they are part of the cooling where particularly good heat transfer can take place by the flowing of a cooling medium due to the surface enlargement as a result of the cavities 44, so that the formation of separate cooling channels can be dispensed with.

A plurality of third layers 43 adjoin the second layers 42, which third layers are arranged as full-area layers (i.e., without gaps) for example in overlap with the first layers 41, or have the surface area thereof.

The cooling elements 32, 34, and 36 described so far are arranged together with the power semiconductor 10 within a housing 50. The preferably closed housing 50 is filled with a medium used for cooling, which can be provided as a liquid medium or as a gaseous medium. Preferably, the medium flows or circulates according to the flow arrows 52, namely in such a way that the medium flows through the cooling elements 32, 34, and 36 in the region of the cross sections of the channels 45.

The housing 50 has in each case one through-opening 54 which is assigned to the respective cooling element 32, 34, 36 and through which a connection element 56 extends. The connection element 56 is a monolithic part of the cooling element 32, 34, and 36, i.e., the cooling element 32, 34, 36 is produced together with the respective connection element 56 in a single manufacturing process.

Outside the housing 50, the connection elements 56 are connected to the connection elements 22, 24, 26 via further contacting layers 58, in particular formed from the same type of material as the cooling elements 32, 34, 36.

The module 100 described so far can be altered or modified in many ways without deviating from the concept of the present invention. It is thus, for example, possible that a housing 50 is dispensed with and the cooling of the power semiconductor 10 takes place by air circulation.

1-11. (canceled).

12. A electronic module, comprising:
at least one power semiconductor electrically connected to a contacting arrangement; and
at least one cooling element configured to at least indirectly cool the at least one power semiconductor, wherein the at least one cooling element is configured as a cooling element produced in an additive manufacturing method, and the at least one cooling element is arranged between the at least one power semiconductor and the contacting arrangement and electrically connects the at least one power semiconductor to the contacting arrangement.

13. The module according to claim 12, wherein the at least one cooling element is built up from a plurality of layers, and the layers form at least one channel for guiding a cooling medium.

14. The module according to claim 12, wherein the at least one cooling element has a lower rigidity in a direction perpendicular to a surface of the power semiconductor than in a direction parallel to the surface of the power semiconductor.

15. The module according to claim 13, wherein, on opposite sides, the at least one cooling element respectively has full-area first and third layers which are electrically connected to the power semiconductor or the contacting arrangement, and in that second layers directly adjoin the full-area first and third layers and form the at least one channel for guiding the cooling medium.

16. The module according to claim 12, wherein at least one cooling element is arranged on each of two opposite sides of the at least one power semiconductor.

17. The module according to claim 12, wherein the at least one power semiconductor is connected to the at least one cooling element using a contacting layer, and in a material of the contacting layer is of the same type as a material of the at least one cooling element.

18. The module according to claim 12, wherein the at least one cooling element and the at least one power semiconductor are arranged within a housing receiving a cooling medium, and/or the contacting arrangement is arranged outside the housing and, through sealed openings formed in the housing, is connected via a connection element to the at least one cooling element.

19. The module according to claim 18, wherein the connection element is configured as a monolithic part of the cooling element.

20. A method for producing an electronic module, comprising the following steps:
providing a power semiconductor having at least one contacting layer;
forming at least one cooling element in an additive manufacturing method on a surface of the at least one contacting layer; and
at least indirectly connecting the at least one cooling element, on a side facing away from the power semiconductor, to a contacting arrangement.

21. The method according to claim 20, wherein, before the at least one cooling element is at least indirectly connected to the contacting arrangement, the at least one power semiconductor and the at least one cooling element are arranged within and the contacting arrangement is arranged outside a housing.

22. The method according to claim 20, wherein the additive formation of the at least one cooling element takes place by selectively melting and subsequently solidifying powder layers using a laser beam, and in that a welding depth and/or an energy input of the laser beam is reduced when lower layers of the at least one cooling element are formed.
